(19) United States
(12) Patent Application Publication
(10) Pub. No.: US 2014/0188411 A1
(43) Pub. Date: Jul. 3, 2014

(54) POWER METER

(71) Applicant: SAMSUNG ELECTRO-MECHANICS CO., LTD., Suwon (KR)

(72) Inventor: Min Gyu KIM, Suwon (KR)

(73) Assignee: Samsung Electro-Mechanics Co., Ltd., Suwon (KR)

(21) Appl. No.: 13/800,748

(22) Filed: Mar. 13, 2013

(30) Foreign Application Priority Data
Dec. 28, 2012 (KR) 10-2012-0157054

(51) Int. Cl. G01R 21/00; G06F 17/00

(52) U.S. Cl. CPC G01R 21/00; G06F 17/00
USPC 702/62

(57) ABSTRACT

There is provided a power meter including a detection unit detecting current consumed in a load terminal and voltage supplied from a power supply terminal to output analog data; and a metering integrated circuit (IC) including an analog-to-digital converter (ADC) converting the analog data into digital data, a processor unit sampling the digital data for a predetermined sampling period, a memory unit storing the sampled digital data output from the processor unit, and a communications module transmitting the sampled digital data stored in the memory unit to an external device.

### CROSS-REFERENCE TO RELATED APPLICATIONS

This application claims the priority of Korean Patent Application No. 10-2012-0157054 filed on Dec. 28, 2012, in the Korean Intellectual Property Office, the disclosure of which is incorporated herein by reference.

### BACKGROUND OF THE INVENTION

1. Field of the Invention

The present invention relates to a power meter capable of transmitting digital data relating to current consumed in a load terminal and voltage supplied from a power supply terminal to external devices.

2. Description of the Related Art

A power meter is an apparatus able to determine a total amount of electric energy by sensing a quantity of current used by using a current sensor and performing a calculation based on a defined voltage.

Recently, interest in next-generation intelligent power networks, smart grids capable of optimizing energy efficiency by bidirectionally exchanging information between a power supplier and a consumer in real time by combining information technology devices with existing power network infrastructure has increased. A consumer may access power-network related information, such as changes in rates, according to power supply and demand situations, and the like, and select an energy source in real time, by digitalizing a power network and using an individual power management device known as a smart meter.

Many functions associated with power quality management are currently being added to the smart meter; however, currently used meters do not have the above functions, and therefore rely on a relatively expensive power quality measuring device to measure signals input and output to and from the currently-used meters.

Patent Document 1, disclosed herein by reference, relates to an electric meter device having a communications module provided therewith, and discloses a method of integrally collecting data from various meters and transmitting the collected data to a remote site via a communications medium, such as a RS485 communications module, or the like, but fails to disclose a method of sampling digital data related to used current and used voltage, or dividing the digital data into a plurality of groups and transmitting the digital data to external devices measuring power quality, by using a universal asynchronous receiver/transmitter (UART), an serial peripheral interface (SPI) communications bus, and a nonvolatile memory included in an existing meter.

### RELATED ART DOCUMENT

(Patent Document 1) Korean Patent Laid-Open Publication No. 10-2005-0027193

### SUMMARY OF THE INVENTION

An aspect of the present invention provides a power meter sampling digital data relating to current and voltage consumed by a load terminal or dividing the digital data into a plurality of groups and transmitting the digital data to an external device measuring power quality, by using an DART, an SPI communications bus, a nonvolatile memory, or the like.

According to an aspect of the present invention, there is provided a power meter, including: a detection unit detecting current consumed in a load terminal and voltage supplied from a power supply terminal to output analog data; and a metering integrated circuit (IC) including an analog-to-digital converter (ADC) converting the analog data into digital data, a processor unit sampling the digital data for a predetermined sampling period, a memory unit storing the sampled digital data output from the processor unit, and a communications module transmitting the sampled digital data stored in the memory unit to an external device.

The communications module may communicate with the external device using universal asynchronous receiver/transmitter (UART) communications.

A data transmission rate of the UART communications may be quicker than a generation rate of the sampled digital data.

According to another aspect of the present invention, there is provided a power meter, including: a detection unit detecting current consumed in a load terminal and voltage supplied from a power supply terminal to output analog data; and a metering IC including an ADC converting the analog data into digital data, a processor unit processing the digital data into a plurality of groups of data having the same duration, a memory unit sequentially storing respective groups of data selected for a predetermined period from among the plurality of groups of data, and a communications module sequentially transmitting the respective groups of data stored in the memory unit to an external device.

The communications module may communicate with the external device using universal asynchronous receiver/transmitter (UART) communications.

The duration may be determined according to a storage capacity of the memory unit.

The predetermined period may be determined according to a data transmission rate of the UART communications.

The communications module may sequentially transmit the respective groups of data stored in the memory unit to the external device after the respective groups of data selected for the predetermined period from among the plurality of groups of data are sequentially stored in the memory unit.

The memory unit may store an N+1-th group of data selected for the predetermined period from among the plurality of groups of data after the communications module transmits an N-th (N is a natural number) group of data selected for the predetermined period from among the plurality of groups of data stored in the memory unit to the external device.

According to another aspect of the present invention, there is provided a power meter, including: a detection unit detecting current consumed in a load terminal and voltage supplied from a power supply terminal to output analog data; a metering IC including an ADC converting the analog data into digital data, a processor processing the digital data to extract a metering parameter therefrom, a memory unit storing the metering parameter, and a communications module transmitting the digital data through serial peripheral interface (SPI) communications; a communications format converting unit converting a communications format of the digital data transmitted through the SPI communications into an USB communications format; and an USB module transmitting the digital data converted into the USB communications format to an external device.

Respective data transmission rates of the SPI communications and the USB communications may be quicker than a generation rate of the digital data.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a block diagram illustrating a power meter according to an embodiment of the present invention; and

FIG. 2 is a block diagram illustrating a power meter according to another embodiment of the present invention.

### DETAILED DESCRIPTION OF THE EMBODIMENTS

Hereinafter, embodiments of the present invention will be described in detail with reference to the accompanying drawings.

The invention may, however, be embodied in many different forms and should not be construed as being limited to the embodiments set forth herein. Rather, these embodiments are provided so that this disclosure will be thorough and complete, and will fully convey the scope of the invention to those skilled in the art.

Throughout the drawings, the same reference numerals will be used to designate the same or like elements.

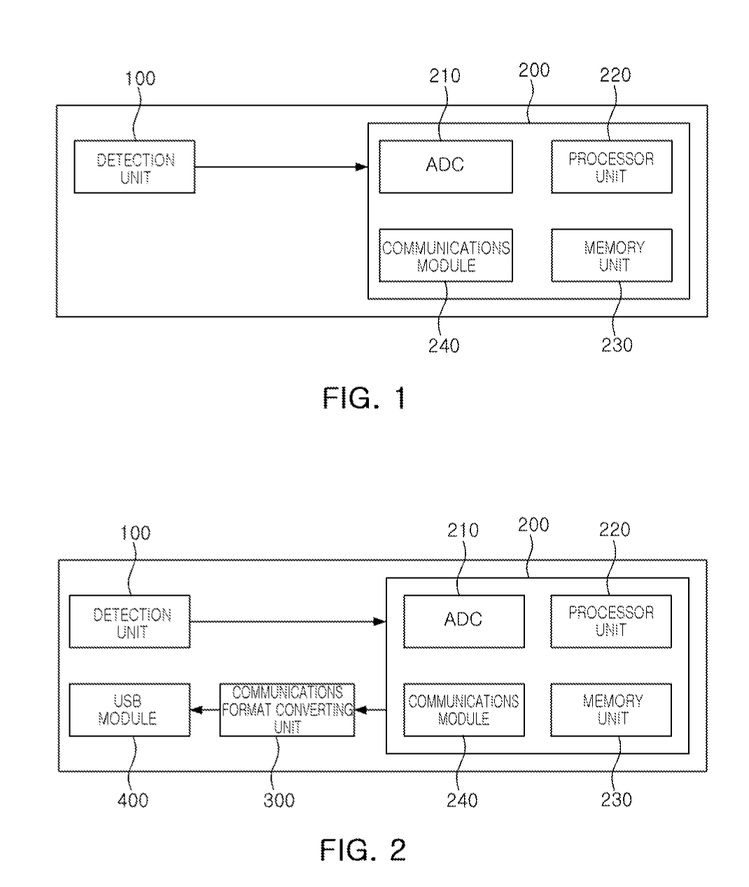

FIG. 1 is a block diagram illustrating a power meter according to an embodiment of the present invention. Referring to FIG. 1, a power meter according to an embodiment of the present invention may include a detection unit 100 and a metering integrated circuit (IC) 200.

The detection unit 100 outputs analog data according to voltage supplied from a power supply terminal and current used by a load terminal. The detection unit generates analog data relating to voltage supplied from the power supply terminal and current used by the load terminal, respectively, and provides the analog data to an analog-to-digital converter (ADC) 210 of the metering IC 200 to be described below through different channels.

The metering IC 200 may include the ADC 210, a processor unit 220, a memory unit 230, and a communications module 240.

The ADC 210 may convert the analog data output from the detection unit 100 into digital data. The ADC 210 samples the analog data for a preset period to generate the digital data.

The processor unit 220 uses an algorithm stored in the memory unit 230 to process the digital data output from the ADC 210, thereby extracting metering parameters therefrom. An example of the metering parameter may include voltage RMS, current RMS, active power, reactive power, a power factor, and the like.

The memory unit 230 may store the metering parameters generated by the processor unit 220. In this case, the memory unit 230 may include a nonvolatile memory, such as a random access memory (RAM) or a flash memory.

When numerical values of the metering parameters detected by the power meter are different from expected numerical values, it may be difficult to confirm factors responsible for errors occurring in the power meter itself.

That is, it cannot be confirmed whether errors occur from the power meter itself or from power supplied from the power supply terminal. In this case, according to the related art, the presence of errors has been determined by adding a power quality measuring device to the power terminal or the load terminal; however, there is a problem in that the power quality measuring device is relatively expensive.

According to the embodiment of the present invention, in order to confirm power quality without the power quality measuring device, the digital data output from the ADC 210 may be transmitted to an external device, such as a computer, and the like, which is able to determine power quality.

According to the embodiment of the present invention, a communications module 240 included in the metering IC 200 is used in order to transmit the digital data, and the metering IC 200 may use universal asynchronous receiver/transmitter (UART) communications to transmit the digital data.

For example, if it is assumed that the ADC 210 samples voltage and current at 3906 Hz per second, voltage signals and current signals are respectively sampled 3906 by 3906, and therefore 7812 pieces of sampled data are generated per second. In this case, if it is assumed that a resolution of the ADC 210 is 16 bits, 4 bytes per sample are generated, such that 31248 bytes (7812×4) of digital data are generated per second.

However, UART communications generally have a data transmission rate of 11520 bytes/1 sec, and therefore a digital data generation rate of 31248 bytes/1 sec is quicker than the data transmission rate of the DART communications, such that all the digital data generated by the ADC 210 may not be transmitted in real time.

In order to solve the problem in that all the digital data generated by the ADC 210 may not be transmitted in real time, the power meter according to the embodiment of the present invention samples the digital data output from the ADC 210 for a predetermined sampling period and transmits the sampled data.

Described in greater detail, the processor unit 220 may sample the digital data for a predetermined sampling period. Next, the digital data sampled by the processor unit 220 may be stored in the memory unit 230 and the sampled digital data stored in the memory unit 230 may be transmitted to the external device via the communications module 240.

For example, digital data generated at a rate of 31248 bytes/1 sec from the ADC 210 may be sampled for a predetermined sampling period set by the processor unit 220 to reduce a rate of 31248 bytes/1 sec of the data generated by the ADC 210 to a rate of 10416 bytes/1 sec ((31248/3) bytes/1 sec) or 7812 bytes/1 sec ((31248/4) bytes/1 sec).

In this case, the generation rate of the digital data sampled by the processor unit 220 is 10416 bytes/1 sec or 7812 bytes/1 sec, which is slower than a UART data transmission rate of 11520 bytes/1 sec, such that the sampled digital data may be stored in the memory unit 230 and be then transmitted to the external device via the communications module 240.

In this case, the external device does not receive the digital data as it is, but receives the sampled digital data in real time, and thus the digital data may not be determined accurately, but a general tendency of the digital data may be determined.

In order to solve the problem in which all digital data generated by the ADC 210 may not be transmitted in real time, the power meter according to the embodiment of the present invention may divide the digital data output from the ADC 210 into a plurality of groups of data having the same duration and sequentially transmit a group of data selected for a predetermined period among the plurality of groups of data to the external device.

Described in detail, the processor unit 220 may divide the digital data into the plurality of groups of data having the same duration.

In this case, in order to divide the digital data output from the ADC 200 into the plurality of groups of data and then store one of the plurality of groups of data and transmit the stored group of data to the external device in a single package, the duration is determined according to a storage capacity of the memory unit 230.

For example, if it is assumed that the storage capacity of the memory unit 230 is 256 Kbytes, the memory unit 230 may store about 65536 (256*1024/4) pieces of sampled data, and when 60 Hz of power is applied, about 130 (7812/60) pieces of sampled data per period are required, and therefore 65536 pieces of sampled data become a quantity of data corresponding to approximately 504 periods, and the memory unit 230 may store digital data generated for about 8.4 seconds. That is, the foregoing duration may refer to a duration corresponding to a quantity of the digital data generated for about 8.4 seconds.

The memory unit 230 may sequentially store respective groups of data selected for a predetermined period from among the plurality of groups of data. For example, the memory unit 230 may store an N-th (N is a natural number) group of data selected for the predetermined period from among the plurality of groups of data and then store an N+1-th group of data selected for the predetermined period from among the plurality of groups of data.

In this case, the predetermined period is determined by the data transmission rate of the communications module 240. When the communications module 240 performs the UART communications with the external device, the data transmission rate is 11520 bytes/1 sec as described above, and in order to transmit 262144 bytes (65536*4 bytes) of data stored in the memory unit 230, about 22.755 seconds are consumed, and therefore the predetermined period may be 5 periods or more.

After the group of data selected for the predetermined period from among the plurality of groups of data is stored in the memory unit 230, the communications module 240 transmits the group of data stored in the memory unit 230 to the external device. That is, the data is not transmitted in real time, but when the group of data output from the ADC 210 is stored in the memory unit 230 in a single package and then the storage thereof is completed, the group of data is transmitted by the communications module 240 in a single package.

Therefore, after the N-th group of data selected for the predetermined period from among the plurality of groups of data is stored in the memory unit 230 and transmitted from the communications module 240 to the external device, the memory unit 230 may store the N+1-th group of data selected for the predetermined period from among the plurality of groups of data.

When the digital data output from the ADC 210 is divided into the plurality of groups of data having the same duration and the group of data selected for the predetermined period from among the plurality of groups of data is stored in the memory unit and then is transmitted to the external device in a single package, the general tendency of the digital data may not be determined, but the digital data in a predetermined duration may be determined accurately, such that the power quality may be determined.

FIG. 2 is a block diagram illustrating a power meter according to another embodiment of the present invention. The power meter according to this embodiment of the present invention may include the detection unit 100 and the metering IC 200.

The detection unit 100 outputs analog data according to voltage supplied from a power supply terminal and current used by a load terminal.

The metering IC 200 may include the ADC 210, the processor unit 220, the memory unit 230, and the communications module 240.

The ADC 210 may convert the analog data output from the detection unit 100 into the digital data. The ADC 210 samples the analog data for a preset period to generate the digital data.

The processor unit 220 uses algorithm stored in the memory unit 230 to process the digital data output from the ADC 210, thereby extracting metering parameters therefrom. An example of the metering parameters may include voltage RMS, current RMS, active power, reactive power, a power factor, and the like.

The memory unit 230 may store the metering parameters generated by the processor unit 220. In this case, the memory unit 230 may include a nonvolatile memory, such as a random access memory (RAM) and a flash memory.

The communications module 240 transmits the digital data output from the ADC 210 by serial peripheral interface (SPI) communications.

A communications format of the digital data transmitted from the communications module 240 by the SPI communications is converted into a USB communications format by a communications format converting unit 300. Next, the USB module 400 may receive the digital data converted into the USB communications format and transmit the received digital data to an external device capable of measuring power quality.

Since transmission rates of the SPI communications and the USB communications are quicker than a digital data generation rate of the ADC 210, the digital data may be transmitted in real time, such that the power quality may be accurately determined from the digital data in all durations.

As set forth above, a power meter according to embodiments of the present invention can sample digital data relating to current and voltage consumed by a load terminal or divide the digital data into a plurality of groups and transmit the digital data to an external device measuring power quality, by using an UART, an SPI communications bus and a nonvolatile memory that are included in an existing power meter, without using a relatively expensive power quality measuring device.

While the present invention has been shown and described in connection with the embodiments, it will be apparent to those skilled in the art that modifications and variations can be made without departing from the spirit and scope of the invention as defined by the appended claims.

What is claimed is:

1. A power meter, comprising:
a detection unit detecting current consumed in a load terminal and voltage supplied from a power supply terminal to output analog data; and
a metering integrated circuit (IC) including an analog-to-digital converter (ADC) converting the analog data into digital data, a processor unit sampling the digital data for a predetermined sampling period, a memory unit storing the sampled digital data output from the processor unit, and a communications module transmitting the sampled digital data stored in the memory unit to an external device.

2. The power meter of claim 1, wherein the communications module communicates with the external device using universal asynchronous receiver/transmitter (UART) communications.

3. The power meter of claim 2, wherein a data transmission rate of the UART communications is quicker than a generation rate of the sampled digital data.

4. A power meter, comprising:
a detection unit detecting current consumed in a load terminal and voltage supplied from a power supply terminal to output analog data; and
a metering IC including an ADC converting the analog data into digital data, a processor unit processing the digital data into a plurality of groups of data having the same duration, a memory unit sequentially storing respective groups of data selected for a predetermined period from among the plurality of groups of data, and a communications module sequentially transmitting the respective groups of data stored in the memory unit to an external device.

5. The power meter of claim 4, wherein the communications module communicates with the external device using universal asynchronous receiver/transmitter (UART) communications.

6. The power meter of claim 4, wherein the duration is determined according to a storage capacity of the memory unit.

7. The power meter of claim 5, wherein the predetermined period is determined according to a data transmission rate of the UART communications.

8. The power meter of claim 4, wherein the communications module sequentially transmits the respective groups of data stored in the memory unit to the external device after the respective groups of data selected for the predetermined period from among the plurality of groups of data are sequentially stored in the memory unit.

9. The power meter of claim 4, wherein the memory unit stores an N+1-th group of data selected for the predetermined period from among the plurality of groups of data after the communications module transmits an N-th (N is a natural number) group of data selected for the predetermined period from among the plurality of groups of data stored in the memory unit to the external device.

10. A power meter, comprising:
a detection unit detecting current consumed in a load terminal and voltage supplied from a power supply terminal to output analog data;
a metering IC including an ADC converting the analog data into digital data, a processor processing the digital data to extract a metering parameter therefrom, a memory unit storing the metering parameter, and a communications module transmitting the digital data through serial peripheral interface (SPI) communications;
a communications format converting unit converting a communications format of the digital data transmitted through the SPI communications into an USB communications format; and
an USB module transmitting the digital data converted into the USB communications format to an external device.

11. The power meter of claim 10, wherein respective data transmission rates of the SPI communications and the USB communications are quicker than a generation rate of the digital data.
